(19) United States
(12) Patent Application Publication
(10) Pub. No.: US 2006/0182206 A1
(43) Pub. Date: Aug. 17, 2006

(54) Communications system, method and device

(75) Inventors: Justin Coon, Bristol (GB); Magnus Stig Torsten Sandell, Bristol (GB)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/267,495

(22) Filed: Nov. 7, 2005

(30) Foreign Application Priority Data
Feb. 16, 2005 (GB) 0503237.0

(51) Int. Cl. H03D 1/04; H04B 7/02

(52) U.S. Cl. 375/346; 375/267

(57) ABSTRACT

A method of estimating channel response in a communications system comprising a transmitting device having a plurality of transmit antennas and a receiving device having at least one receive antenna, the method comprising: (a) Superimposing training sequences onto transmit data to be transmitted by the transmit antennas in order to form a composite message, wherein the training sequences for each transmit antenna are arranged such that they are non-overlapping in the frequency domain; (b) Transmitting the composite message from step (a); (c) Receiving data at the receiving device and then performing the following steps across all channels i. Equalising received data to remove channel distortion; ii. detecting an estimate for the transmit data; iii. using the estimate of the transmit data from step (c)(ii) in order to derive an estimate of the received training sequences as modified by the channel response from the received data; iv. comparing the estimate of channel modified training sequences from step (c)(iii) with the original training sequences in order to estimate the channel response

This invention relates to a communications method for use in a communications system in which a transmitting device has a plurality of transmit antennas and a receiving device has at least one receive antenna. The invention also relates to a communications system and device using such a method. The invention particularly relates to channel estimation and tracking techniques in multiple input and multiple output systems.

A typical wireless network comprises a plurality of mobile terminals, each in radio communication with an access point or base station of the network. The access points may also be in communication with a central controller that in turn may have a link to other networks, for example a fixed Ethernet-type network. Until recently considerable effort was put into designing systems so as to mitigate for the perceived detrimental effects of multi-antenna propagation, especially prevalent in wireless LAN (local area network) and other mobile communications environments. However the described work G. J. Foschini and M. J. Gans, “On limits of wireless communications in a fading environment when using multiple antennas” Wireless Personal Communications vol. 6, no. 3, pp. 311-335, 1998 has shown that by utilising multiple antenna architectures at both the transmitter and receiver, a so-called multiple-input multiple-output (MIMO) architecture, vastly increased channel capacities are possible. Attention has also turned to the adoption of space-time coding techniques for wideband channels. Typically channel state information (CSI) for detection of such coding is acquired via training sequences and the resulting CSI estimates are then fed to a space-time decoder along with the received signal.

A particular problem arises in a communications link where a transmitter with more than one transmit antenna is employed, since signals received from different transmit antennas interfere with one another. This results in so-called multi-stream interference (MSI) and causes decoding difficulties. The potential advantage, however, is greatly increased throughput (that is, a higher bit rate) for such a communications link. In this type of MIMO (Multiple-input Multiple-output) communication link the “input” (to a matrix channel) is provided by the transmitter's plurality of transmit antennas and the “output” (from a matrix channel) is provided by a plurality of receive antennas. Thus each receive antenna receives a combination of signals from all the transmitter's transmit antennas which must be unscrambled.

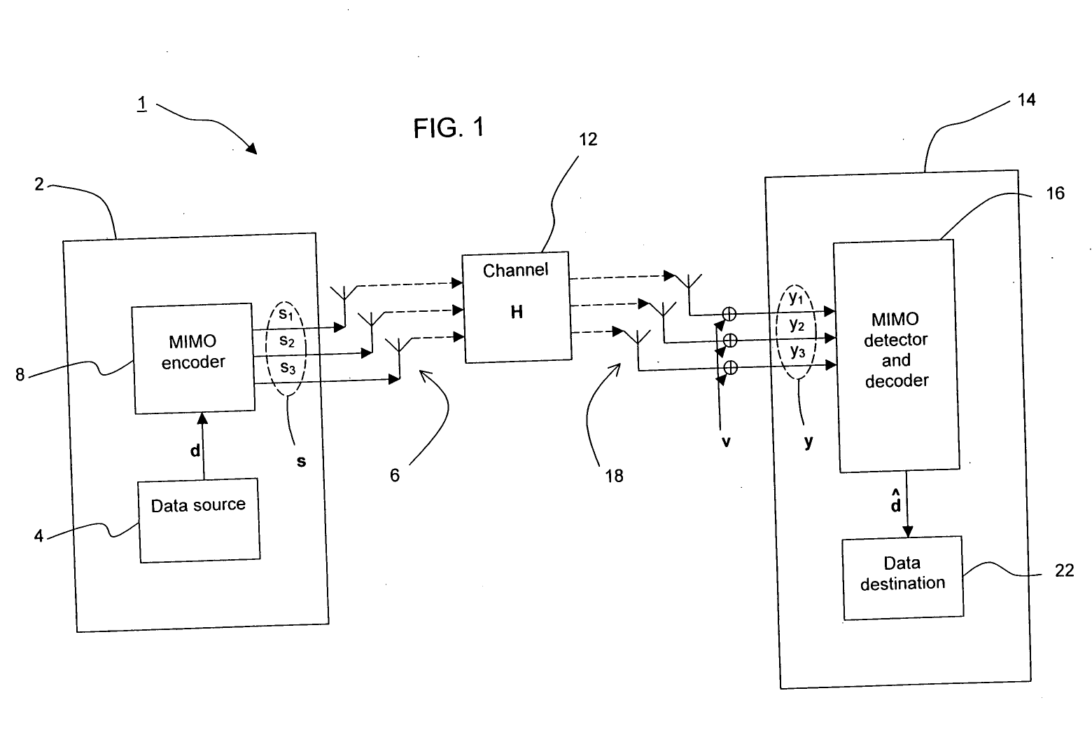

FIG. 1 of the accompanying drawings is a schematic diagram illustrating a typical MIMO communication system 1 comprising a transmitting device 2 and a receiving device 14. In the transmitting device 2, a data source 4 provides an information symbol vector d to a MIMO encoder 8 which encodes the symbol vector d as T code symbols s₁ s₂ . . . , s_{T}. The T code symbols s₁ s₂ . . . , s_{T} can be represented as transmit symbol vector s, and in this example, T is three. The T code symbols s₁ s₂ . . . , s_{T} are then transmitted separately and simultaneously from T transmit antennas 6 respectively. An example of a MIMO encoder 8 is found by a direct mapping of input symbol dᵢ to output symbol sᵢ.

In the receiving device 14, a plurality R of receive antennas 18 receives respectively signals y₁, . . . y_{R}, represented as symbol vector y. For a narrowband channel the channel response of the channel 12 between the transmitting device 2 and the receiving device 14 are represented by an R×T channel response matrix H (having R rows and T columns of complex channel coefficients), with the noise contribution at the receiver being represented by the R-dimension noise vector v. Using this model,
y=Hs+v (1)

The receive signals y are then input to a MIMO detector and decoder 16, along with an estimate of the channel response matrix, H. Channel estimation in the MIMO detector 16 can be achieved in a number of well-documented ways. These inputs to the MIMO detector 16 can be used to form an estimate ŝ of the transmit symbol vector, or to directly form an estimate of the information symbol vector d. An example MIMO detector 16 corresponding to the example encoder described above is to generate a linear estimator matrix W equal to H⁻¹, so that the estimate ŝ of the transmit symbol vector is given by:
ŝ=Wy (2)

This estimate ŝ of the transmit symbol vector is then decoded by the MIMO decoder 16 by performing the reverse of the encoding operation performed by the MIMO encoder 8 to produce an estimate \hat{d} of the original information symbol vector d, and this estimate \hat{d} is passed to the data destination 22.

In the example above, the linear estimator matrix W effectively separates the plurality of transmitted signals arriving at the receive array. Non-linear estimators are more optimal and may employ maximum likelihood (ML) or maximum a posteriori probability (MAP) estimation techniques.

In the above example, data transmission over the channel 12 from multiple users can be handled using time division multiplexing in combination with the spatial multiplexing of MIMO so that the sequence of operations above is performed in one time frame for one user and for another user in the next time frame.

The state of the wireless channel (the channel response, 12) varies over time (e.g. due to movement by the transmitter, the receiver, or even people, cars, and similar objects). Therefore in order to achieve and maintain good performance a wireless communication systems will need to estimate the channel response and also track the response over time.

Typically, the channel response is estimated by transmitting training messages that are known to both the transmitter and the receiver and then using these messages at the receiver to estimate the current state of the channel.

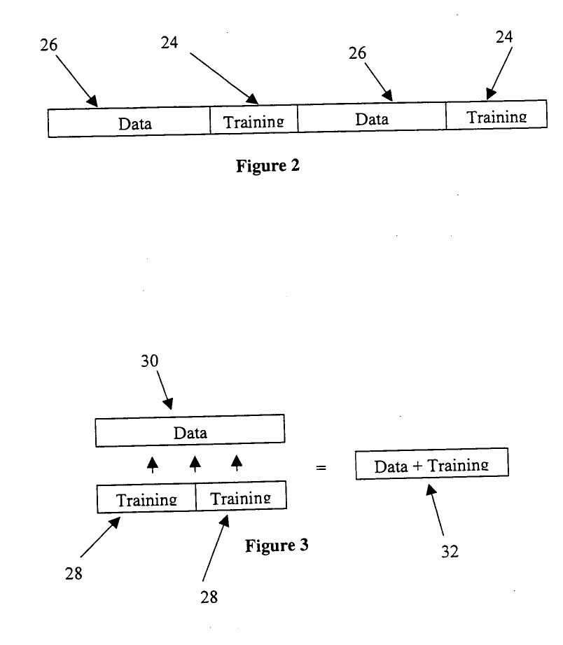

FIG. 2 shows a system wherein the training message 24 is periodically transmitted in order to enable updates of the channel response to be made. It can be seen in this case that the training data 24 and message data 26 are interleaved. An example of such a system is described in Furuskar, A., Mazur, S., Muller, F., and Olofsson, H. “EDGE: Enhanced Data Rates for GSM and TDMA/136 Evolution,” IEEE Personal Communications, vol. 6, no. 3, pp. 56-66, 1999.

It is, however, noted that conventional channel estimation methods that interlace data with training messages are generally undesirable in mobile environments since the training messages constitute redundant information and must be transmitted often, which causes a reduction in throughput.

Temporal variations in the channel response may be tracked by means of an adaptive tracking method. For example, the response may be continually tracked by various implementations of least-mean squares (LMS) adaptation, a recursive least squares (RLS) algorithm, or by a more general technique known as Kalman filtering. These algorithms typically use data that has been detected at the receiver to track variations in the channel state.

However, such adaptive tracking methods become very complex when applied to MIMO architectures.

As an alternative to the above methods of estimating and tracking the channel response, training sequences/messages can instead be superimposed onto the data. FIG. 3 illustrates a system wherein the training messages 28 are superimposed onto the message data 30 to form a composite message 32. This technique has the advantage that it allows the channel to be estimated without compromising the bit rate of the system.

Systems which superimpose training messages onto the data require that the data and noise at the receiver average to zero (zero-mean) and also that the training messages are periodic in order for the channel to be estimated. Under these constraints, the channel can be estimated by first allowing the receiver to collect a predetermined number of received symbols, after which an average of these symbols is taken. Since the data and the noise are zero-mean, these quantities ideally do not significantly affect the average (i.e. they average to zero). Instead, the average is simply the training signal distorted by the channel. Since the training signal is known at the receiver, the channel can be estimated by employing any number of techniques, such as the least squares (LS) technique or maximum likelihood (ML) methods.

Examples of systems in which training messages are superimposed onto the data are described in (i) Meng, X. and Tugnait, J. “MIMO channel estimation using superimposed training,” ICC 2004 and (ii) Orozco-Lugo, A., Lara, M., and McLemon, D. “Channel estimation using implicit training,” IEEE Transactions on Signal Processing, vol. 52, no. 1, January 2004.

It is noted that techniques that use superimposed training messages along with averaging followed by channel estimation can cause delays in the communication system due to the potentially large latency associated with the collection of an appropriate number of received symbols prior to channel estimation. Also, these techniques are reasonably complex and do not perform very well unless more sophisticated iterative ML techniques are applied with them.

It is therefore an object of the present invention to provide a communication system, communication devices and a method of estimating and tracking channel response in communication systems which substantially mitigates the above mentioned problems. It is a further object of the present invention that the channel can be estimated and tracking while maintaining low overhead and low complexity.

According to a first aspect the present invention provides a method of estimating channel response in a communications system comprising a transmitting device having a plurality of transmit antennas and a receiving device having at least one receive antenna, the method comprising
a. Superimposing training sequences onto transmit data to be transmitted by the transmit antennas in order to form a composite message, wherein the training sequences for each transmit antenna are arranged such that they are non-overlapping in the frequency domain
b. Transmitting the composite message from step (a)
c. Receiving data at the receiving device and then performing the following steps across all channels
   i. Equalising received data to remove channel distortion;
   ii. detecting an estimate for the transmit data;
   iii. using the estimate of the transmit data from step (c)(ii) in order to derive an estimate of the received training sequences as modified by the channel response from the received data;
   iv. comparing the estimate of channel modified training sequences from step iii with the original training sequences in order to estimate the channel response

The present invention provides a method of estimating channel response in a communications system. Training sequences that are non-overlapping in the frequency domain are superimposed onto information being transmitted by a plurality of transmit antennas. The receiver side of the system derives an estimate of the training sequences as modified by the channel response and then compares them to the original training sequences (which are provided to the receiver device separately, e.g. by being pre-loaded into a memory storage).

The receiving device may comprise a single receive antenna or more preferably a plurality of receive antennas.

If the receiving device has stored a previous estimate of the channel response then step (c)(iii) above may conveniently comprise subtracting the estimate of the transmit data (from step (c)(ii)) as modified by the previous estimate of the channel response from the received data. This will derive an estimate of the received training sequences as modified by the current channel response. Step (c)(iv) then comprises updating the previous estimate of the channel response by comparing the channel modified training sequence from step (c)(iii) with the original training sequences (which are also stored in the receiving device).

The training data preferably comprises training sequences which are unique to each antenna.

Any equalisation technique may conveniently be used in the receiving device, for example, linear zero forcing (ZF), minimum mean square error (MMSE) equalisation, non-linear maximum likelihood (ML) or decision feedback.

If an estimate of the channel response, H, is required in the equalisation step then a previous estimate may be used.

Preferably, the receiving device periodically updates the estimate of the channel response based on the received data.

The training sequences are designed such that they are non-overlapping in the frequency domain, i.e. the discrete Fourier transforms of the training sequences have non-overlapping and non-zero elements.

In detail the structure of the sequences may conveniently be as follows: For a data block of length K, the normalized discrete Fourier transform (DFT) of the length-K training sequence at the qth transmit antenna is defined by the column vector x_{q} and

$${\prod }_{q = 1}^{n} {X}_{q} = 0$$

where X_{q} is a diagonal matrix with the elements of x_{q} on the diagonal, 0 is a K×K matrix of zeros, and the quantity n denotes the number of transmit antennas in the system.

Preferably, training sequences that are designed according to the above format are arranged such that
A=\sqrt{K}[X₁F_{L+1} . . . XₙF_{L+1}]
is a unitary matrix up to a scalar multiple where F_{L+1} is a matrix comprising the first L+1 columns of the normalized DFT matrix. The parameter L must be greater than or equal to the memory order of the channel impulse response (i.e. L+1 must be greater than or equal to the total number of channel coefficients), which is assumed to be known here.

It is noted that superimposing training sequences as described above onto the transmit data will affect the total transmit power that is being transmitted from the plurality of transmit antennas. In the event that such power fluctuations are detrimental to the operation and efficiency of the communications system then the training sequences can conveniently be manipulated such that they are sparse (i.e. such that the training sequence comprises proportionally a lower number of training symbols and a larger number of zero elements).

Preferably the transmitted data is processed into a block format. The end of each block may be conveniently padded with zeros in order to reduce the effects of intersymbol interference.

Preferably, the estimate of the channel response is tracked over time by deriving an estimate for the channel response for each received data block.

Since the training sequences are non-overlapping not all of the specific channel frequency response coefficients will be updated during the estimation process. Any coefficients that have not been updated can conveniently be estimated by resetting to zero value and then interpolating based on those coefficients that have been updated.

If computational resources within the communications system are limited then the interpolation step need not be performed for every iteration of the estimation process, i.e. interpolation may be performed at a longer period than the tracking period.

Preferably the estimate of the channel response is achieved by use of a recursive least square algorithm.

The estimation of the channel response may require an initial value of H to be known to the receiving device. There are a number of options for obtaining a first value for the channel response:
1) The receiver can randomly generate an estimate of H. Over a number of iterations the estimate will converge towards the actual channel response.
2) For a system in which the data and noise are zero mean the receiver could collect a large number of data blocks and then average out the data in order to calculate an initial value of H.
3) The transmitter could initially transmit a training sequence without associated message data.

According to a second aspect the present invention provides a communications system comprising:

a transmitting device having a plurality of transmit antennas and means for superimposing training data onto transmit data to be transmitted by the transmit antennas, the training data being arranged such that training sequences are non-overlapping in the frequency domain;

a receiving device having a plurality of receive antennas and
i. means for equalising received data to remove channel distortion,
ii. means for detecting an estimate for the transmit data,
iii. means for deriving an estimate of the received training data as modified by the channel response from the received data using the estimate of the transmit data, and
iv. means for comparing estimate of received training data from step iii with original training data in order to estimate the channel response.

According to a third aspect the present invention provides a communications method for use by a transmitting device having a plurality of transmit antennas in a communications system also comprising a receiving device having at least one receive antenna, the method comprising
a) superimposing training sequences onto transmit data to be transmitted by the transmit antennas
b) transmitting the data from step (a)
   wherein the training sequences for each transmit antenna are arranged such that they are non-overlapping in the frequency domain.

According to a fourth aspect the present invention provides a transmitting device having a plurality of transmit antennas for use in a communications system also comprising a receiving device having at least one receive antennas, the transmitting device comprising means for superimposing training sequences onto transmit data to be transmitted by the transmit antennas wherein the training sequences for each transmit antenna are arranged such that they are non-overlapping in the frequency domain.

According to a fifth aspect the present invention provides a communications method for use by a receiving device having at least one receive antenna in a communications system also comprising a transmitting device having a plurality of transmit antennas, the method comprising
a) receiving data that has been transmitted from the transmitter, the transmit message comprising training sequences superimposed onto transmit data, and then performing the following steps across all channels
b) Equalising received data to remove channel distortion,
c) detecting an estimate for the transmit data,
d) using the estimate of the transmit data from step (c) in order to derive an estimate of the received training sequences as modified by the channel response from the received data,
e) comparing the estimate of channel modified training sequences from step (d) with original training sequences in order to estimate the channel response

According to a sixth aspect the present invention provides a receiving device having at least one receive antenna for use in a communications system also comprising a transmitting device having a plurality of transmit antennas and transmitting training sequences superimposed onto transmit data, the receiving device comprising
a) means for equalising received data to remove channel distortion,
b) means for detecting an estimate for the transmit data,
c) means for deriving an estimate of the received training data as modified by the channel response from the received data using the estimate of the transmit data,
d) means for comparing the estimate of channel modified training sequences from step (c) with original training sequences in order to estimate the channel response

According to a seventh aspect of the present invention there is provided an operating program which, when run on a communications device, causes the device to carry out a method according to the third or fifth aspect of the present invention.

According to an eighth aspect of the present invention there is provided an operating program which, when loaded into a communications device, causes the device to become one according to the fourth or sixth aspect of the present invention.

The operating program may be carried on a carrier medium, which may be a transmission medium or a storage medium.

The present invention will now be described with reference to the following non-limiting preferred embodiments in which:

FIG. 1, discussed hereinbefore, is a schematic diagram illustrating a typical MIMO communication system;

FIG. 2, discussed hereinbefore, illustrates a system which utilises periodic transmission of training messages;

FIG. 3, discussed hereinbefore, illustrates a system which utilises training messages superimposed onto data;

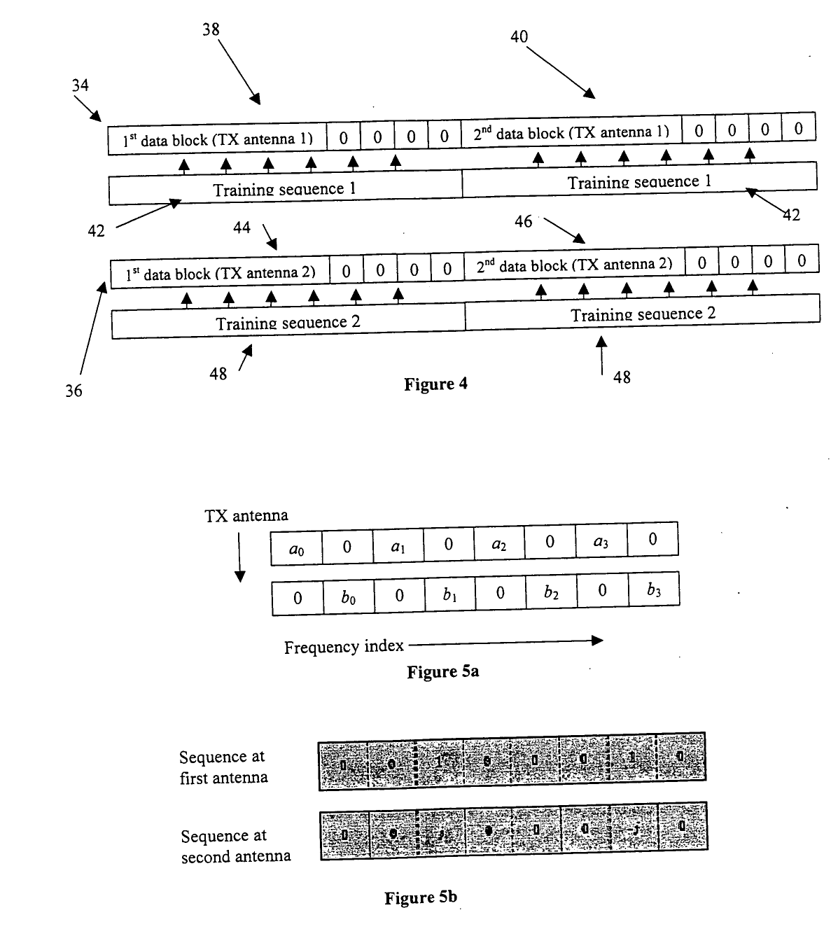

FIG. 4 shows training data being superimposed onto data for transmission from a transmitter in accordance with the present invention

FIGS. 5a and 5b show examples of training sequences that may be used in the present invention

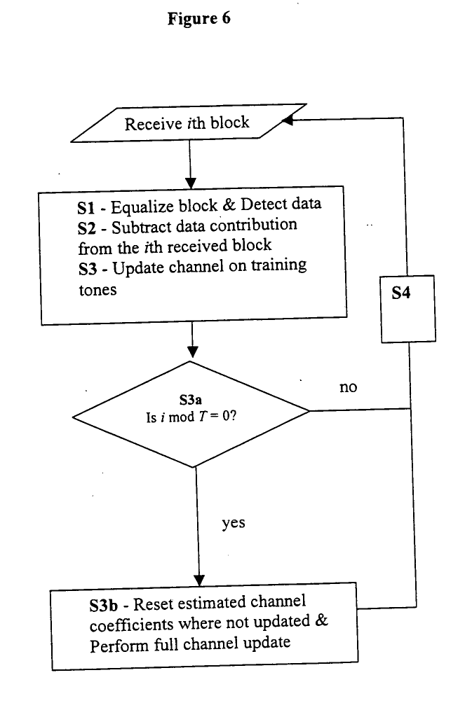

FIG. 6 shows a flowchart of the channel tracking method of the present invention

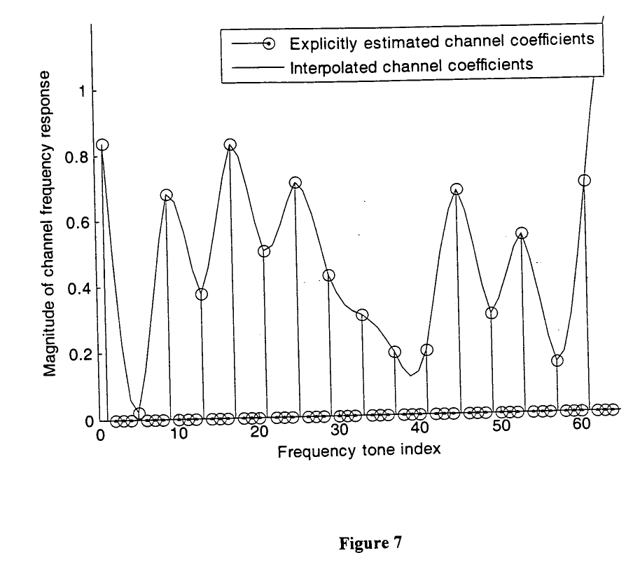

FIG. 7 shows a graph depicting an interpolation step in the method of FIG. 6.

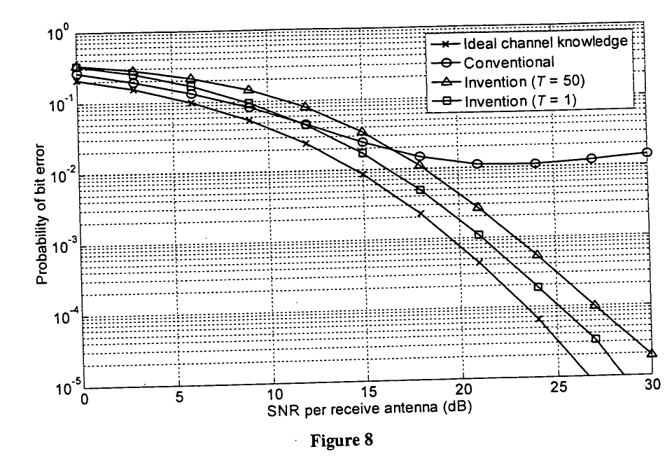

FIG. 8 shows a graph comparing the performance of the tracking method of the present invention with a conventional technique utilising interleaved training messages.

In the present invention training data is superimposed onto data at the transmitter and a tracking and estimation algorithm is applied at the receiver in order to estimate and track the channel response of the communication system. FIGS. 4 and 5 relate to the transmitter side of the communications system of the present invention. FIGS. 6 and 7 relate to the receiver portion of the communications system of the present invention.

FIG. 4 shows how training data is superimposed onto data for transmission from a transmitter in the present invention. As indicated by the presence of two data streams 34, 36 in FIG. 4 the transmitter depicted comprises two transmit antennas. The skilled person will, however, appreciate that the transmitter may, in reality, comprise more than two antennas.

The data to be transmitted by the transmit antennas is processed into block format (Note the data may be processed by either single carrier or multiple carrier techniques).

Transmit antenna 1 (denoted by the upper data stream 34 in the Figure) sends two data blocks 38, 40. A training sequence 42 (training sequence 1) is superimposed onto each data block.

Transmit antenna 2 also transmits two data blocks 44, 46. A training sequence 48 (training sequence 2) is superimposed onto the data blocks of antenna 2.

The end of each data block is padded with zeros. This is an optional step which mitigates against intersymbol interference (ISI) which can arise when the channel distorts preceding blocks. Padding the data block can thus improve system performance.

The training sequences are unique to a particular antenna.

In detail, the structure of the training sequences that are used in the present invention is as follows.

For a data block of length K, the normalized discrete Fourier transform (DFT) of the length-K training sequence at the qth transmit antenna is defined by the column vector x_{q} and

$${\prod }_{q = 1}^{n} {X}_{q} = 0$$

where X_{q} is a diagonal matrix with the elements of x_{q} on the diagonal, 0 is a K×K matrix of zeros, and the quantity n denotes the number of transmit antennas in the systems.

Preferably, training sequences that are designed according to the above format are arranged such that
A=\sqrt{K}[X₁F_{L+1} . . . XₙF_{L+1}]
is a unitary matrix up to a scalar multiple where F_{L+1} is a matrix comprising the first L+1 columns of the normalized DFT matrix. The parameter L must be greater than or equal to the memory order of the channel impulse response (i.e. L+1 must be greater than or equal to the total number of channel coefficients), which is assumed to be known here.

It is noted that when A is designed as a unitary matrix (up to a scalar multiple) the best possible channel estimate is obtained (in the sense of mean-square error (MSE)).

The training sequences are designed such that they are non-overlapping in the frequency domain (i.e. the DFTs of the training sequences have non-overlapping non-zero elements). An example of this property is illustrated in FIG. 5a.

It is noted that in general the training sequences defined above will not be sparse (that is to say that across all the transmit antennas there will be a non-zero element at each symbol position in a K length block). This will in turn lead to an increase in the total required transmit power. In the event that the increased transmit power is a problem then the sequences can be specially constructed to avoid this problem. Such sequences, which are a sub-set of the training sequences defined above, may be constructed as follows:
1. Choose a length-K/n sequence as

$${δ}_{k - l} = \{ \begin{matrix}α , & k = l such that 0 \leq k , l \leq K / n - 1 \\ 0 , & otherwise\end{matrix}$$
where α is a complex number that is not zero.
2. Repeat this sequence n times to make a length-K sequence.
3. Using this sequence, denoted by x₁, construct n−1 other sequences (x₂, x₃, . . . , xₙ) by performing the following operation:

$${x}_{q ; m} = {x}_{1 ; m} {ⅇ}^{j \frac{2 π m ( q - 1 )}{K}}$$
where x_{q;m} denotes the mth element of x_{q} and j=\sqrt{−1}. Note that m is defined from 0 to K−1.

An example of sparse sequences constructed according to the above method is shown in FIG. 5b. In this instance K=8 and n=2. These sequences, which are depicted in FIG. 5b in the time domain, do not overlap in the frequency domain. Consequently, they can be superimposed on the transmitted information sequences and used in the present invention as described above. Alternatively, the information symbols located at the same positions as the non-zero elements of the sparse training sequences can be replaced with the corresponding training symbols. Composite information/training sequences that are constructed in this manner do not, in general, suffer from an increase power since no training symbols are being directly superimposed onto information symbols. In this case, the aforementioned receiver algorithm can still be applied.

FIG. 6 illustrates the basic concept underlying the estimation and tracking algorithm performed at the receiver.

To begin, an ith data block is received by the receiver. This received data comprises training sequences superimposed over message data that has been modified by the communication channel (H). It is noted that the receiver has knowledge of the training sequences used by the transmit antennas in the transmitter.

The received data is then manipulated via a series of steps (S1, S2 and S3) in order to update the estimate of the channel response, Ĥ, held in the receiver.

In Step 1 (S1) the received data is first equalised (to remove channel distortion) and an estimate of the transmitted data is derived (data detection).

In Step 2 (S2), the estimate of the data derived in S1 is subtracted from the received signal in order to recover the training sequences as modified by the communications channel.

Since the receiver has knowledge of the training sequences used in the transmitter the channel modified training data can be compared with the original training sequences in order to update the estimate of the channel response within the receiver. This is step 3 (S3).

It is noted from FIG. 5 that the training sequences comprise a mixture of zero and non-zero components in the frequency domain. As a result the channel response estimate derived in S3 will correspond only to those tones (frequencies) that have had training symbols superimposed upon them. The remaining channel frequency response coefficients can be interpolated. In order to reduce processing power this interpolation step need only be performed periodically.

The optional interpolation step is depicted in FIG. 6 by the branching of the flow chart lines at step 3a. If a full estimate of H is to be performed the channel coefficients that were not updated are reset and then the remaining coefficients are interpolated at Step 3b. Following interpolation the (i+1)th block is received (Step S4) and process steps S1 to S3 begin again.

If a full estimate is not required at S3a then the receiver proceeds directly to processing the (i+1)th block of received data (Step S4).

In more detail the receiver algorithm is as follows:

Step S1—the receiver receives the ith data block. Using the same model as described in relation to FIG. 1 above the received data y is represented by
y=Hx+Hs+v (3)
where x represents the training sequence vector and y, H and v are as described in FIG. 1.

The received data is then equalised. Examples of suitable equalisation techniques include linear zero forcing (ZF), minimum mean-square error (MMSE) equalisation and non-linear ML or decision feedback equalisation (DFE). If any of the equalisation techniques require knowledge of the channel response H then a previous estimate H can be used.

Using the above model (Equation 3), S1 can be represented as comprising the following sub-steps:
Step 1.1—the training vector x is stored in the receiver. Additionally the receiver comprises a previous estimate of the channel response, Ĥ. Therefore an estimate ŝ of the transmit vector and system noise v can be derived by subtracting Ĥx from y:
   y−Ĥx≈Hs+v (4)
Step 1.2—the remaining message (Hs+v) can be equalised, for example, by multiplying by Ĥ⁻¹:
   Ĥ⁻¹(y−Ĥx)≈s+Ĥ⁻¹v (5)
Step 1.3—an estimate of s, denoted by ŝ, is then derived.

Step S2—the receiver now comprises an estimate of the channel response Ĥ, the training vector x and an estimate ŝ of the transmitted data vector. Subtracting the estimated data contribution Ĥŝ from the actual data received at the receiver enables Hx to be recovered,
i.e. y−Ĥŝ≈Hx(+v) (6)

Step S2 is performed over all antennas and can more fully be described as follows. If the previous estimate of the channel frequency response from the qth transmit antenna to the pth receive antenna is denoted by h_{p,q}(i−1) and the DFT of the ith vector of symbols received at the pth receive antenna is denoted by yₚ(i), then the contribution of the data to the total received message subtracted from yₚ(i) results in the vector

$${z}_{p} ( i ) = {y}_{p} ( i ) - {\sum }_{q = 1}^{n} {s}_{q} ( i ) {h}_{p , q} ( i - 1 ) \qquad ( 7 )$$

where S_{q}(i) is a diagonal matrix with the elements of the DFT of the detected symbol vector on the diagonal [Note: S_{q}(i) and h_{p,q}(i−1) in (7) correspond to ŝ and Ĥ in (6)]. This step is performed for each of the vectors received at the various receive antennas.

[It should be noted that the estimation and tracking algorithm has been described above in relation to transmit data s that has not been encoded by an encoder at the transmitter. If an encoding step is included at the transmitter then the transmit vector s represents encoded data symbols d.

If an encoder is used in the transmitter then Step S1.3 could, in this instance, additionally include a decoding step to decode ŝ in order to derive an estimate \hat{d} of the original information symbol d. Step 2 would then additionally re-encode the decoded data from step 1.3]

Step S3—The receiver has recovered Hx from step S2. The training sequence x is known to the receiver and so the channel response can therefore be estimated and updated.

In other words, for each of the channels, the frequency response coefficients corresponding to frequency tones over which training information was superimposed are updated using a version of an RLS algorithm.

The algorithm has two metrics that are modified with each received block and subsequently used to update the channel estimate.

The metric r_{p;k}(i), defined on the kth tone for the pth receive antenna, is updated for all K tones as follows:
r_{p;k}(i)=ρr_{p;k}(i−1)+z_{p;k}(i)
where z_{p;k}(i) is the kth element of zₚ(i) and ρ is a constant that is close to, but less than, one (1).

The second metric v_{p,q;k}(i), defined on the kth tone for the qth transmit antenna and the pth receive antenna, is updated for all K tones as follows:
v_{p,q;k}(i)=ρv_{p,q;k}(i−1)+x_{q;k}
where x_{q;k} is the kth element of the training sequence x_{q}. These metrics are updated for all values of p, q, and k.

Once the ith metrics are computed, the channel estimate can be updated. If a full update of the channel response is required then, firstly, the set of frequency tones over which training information was transmitted from the qth transmit antenna is updated by calculating r_{p;k}(i) divided by v_{p,q;k}(i). Secondly, the remaining tones are then reset (to zero) and updated values for these tones are calculated by interpolation from the other updated values.

If a full update of the channel response is not required then the interpolation stage is not performed and the remaining tone values are not reset.

The above description of the channel response update can be represented by the following rule:

If i mod T=0 (full update required),

$${h}_{p , q ; k} ( i ) = \{ \begin{matrix}\frac{{r}_{p ; k} ( i )}{{v}_{p , q ; k} ( i )} , & k ∈ {Ω}_{q} \\ 0 , & otherwise\end{matrix} , ∀ p , q$$

and then interpolate to estimate remaining channel coefficients (see below). If a full update is not required then,

$${h}_{p , q ; k} ( i ) = \{ \begin{matrix}\frac{{r}_{p ; k} ( i )}{{v}_{p , q ; k} ( i )} , & k ∈ {Ω}_{q} \\ {h}_{p , q ; k} ( i - 1 ) , & otherwise\end{matrix} , ∀ p , q .$$

In the rule above, Ω_{q} denotes the set of frequency tones over which training information was transmitted from the qth transmit antenna. Also, the notation “mod T” denotes modulo-T arithmetic where T is a design parameter that specifies how often the full channel estimate is updated in terms of received block intervals.

For example, if T is small, the full channel is updated often. If T is large, only those channel frequency response coefficients that correspond to tones over which training information was transmitted are updated often. The remaining channel frequency response coefficients are updated infrequently and so in this instance a full channel estimate is only calculated infrequently.

Step S4—the receiver processes the (i+1)th block of data

The interpolation specified in the rule above refers to any technique that can be employed to interpolate between the channel frequency response coefficients that are explicitly estimated in order to recover the full channel frequency response (e.g. Fourier interpolation, spline, linear, etc.). An example of this interpolation is depicted in FIG. 7.

The above description of the receiver based estimation algorithm has assumed that the receiver has a previous estimate of the channel response to call upon. At system start-up (i.e. before an estimate of H has been derived) there are a number of options:
a. The receiver can randomly generate an estimate of H. Over a number of iterations the estimate will converge towards the actual channel response.
b. For a system in which the data and noise are zero mean the receiver could collect a large number of data blocks and then average out the data in order to calculate an initial value of H, i.e. the first estimate of H could be derived by the process described in Meng, X. and Tugnait, J. “MIMO channel estimation using superimposed training,” ICC 2004.
c. The transmitter could initially transmit a training sequence without associated message data. In this case, the update metrics are initialised as follows:

$${r}_{p ; k} ( 0 ) = \frac{1}{1 - ρ} {x}_{q ; k} {h}_{p , q ; k} ( 0 )$$

$$and$$

$${v}_{p , q ; k} ( 0 ) = \frac{1}{1 - ρ} {x}_{q ; k}$$

for all values of k, q, and p. If no such channel estimate is available, the metrics r_{p;k}(0) and v_{p,q;k}(0) are initialised to zero (0) for all values of k, q, and p. Also, all initial estimates of the channel frequency response coefficients are set to zero (0) in this case.

Unlike conventional channel estimation methods that use data interlaced with training messages, the present invention uses training that is superimposed onto the transmitted data.

The complexity of the tracking technique of the present invention is very small since each update operation only requires a few scalar multiplications. This is not the case in other systems that use superimposed data where potentially large matrix multiplications must be carried out to estimate the channel. Also, these conventional systems do not include a feedback step as described in steps 2 to 4 detailed above. Instead, conventional systems compensate by employing very complex iterative ML techniques to improve performance.

The performance of the present invention is tuneable through the parameters ρ and T. This adaptability allows this invention to be customized for use in many different mobile environments.

FIG. 8 illustrates the efficacy of this invention in terms of performance when it is implemented in an environment typical of an indoor office.

Embodiments of the invention have been mainly described in the context of a MIMO system. Embodiments of the invention may also be employed in non-wireless applications such as magnetic or optical disk drive read head circuitry where, for example, multiple layers of a disk in effect act as multiple transmitters, one or more heads receiving read data influenced by “transmitted” signals from more than one layer.

It will be appreciated that operation of one or both of the transmitting device 2 and receiving device 14 can be controlled by a program operating on the device. Such an operating program can be stored on a computer-readable medium, or could, for example, be embodied in a signal such as a downloadable data signal provided from an Internet website. The appended claims are to be interpreted as covering an operating program by itself, or as a record on a carrier, or as a signal, or in any other form.

The scope of protection claimed in the appended claims is to be determined on the basis of the description, with reference to the accompanying drawings, but not to the extent that features of the specific embodiments of the invention are to be construed as limitations on the scope of features of the claims.

1. A method of estimating channel response in a communications system comprising a transmitting device having a plurality of transmit antennas and a receiving device having at least one receive antenna, the method comprising
a. Superimposing training sequences onto transmit data to be transmitted by the transmit antennas in order to form a composite message, wherein the training sequences for each transmit antenna are arranged such that they are non-overlapping in the frequency domain
b. Transmitting the composite message from step (a)
c. Receiving data at the receiving device and then performing the following steps across all channels
i. Equalising received data to remove channel distortion;
ii. detecting an estimate for the transmit data;
iii. using the estimate of the transmit data from step (c)(ii) in order to derive an estimate of the received training sequences as modified by the channel response from the received data;
iv. comparing the estimate of channel modified training sequences from step (c)(iii) with the original training sequences in order to estimate the channel response

2. A method of estimating channel response as claimed in claim 1 wherein the receiving device comprises a previous estimate of the channel response and step (c)(iii) comprises subtracting the estimate of the transmit data as modified by the previous estimate of the channel response from the received data and step (c)(iv) comprises updating the previous estimate of the channel response.

3. A method of estimating channel response as claimed in claim 1 wherein the training sequence at any one transmit antenna is unique to that antenna.

4. A method of estimating channel response as claimed in claim 1 wherein received data is equalised by one of the following methods: linear zero forcing (ZF), minimum mean square error (MMSE) equalisation, non-linear maximum likelihood (ML) or decision feedback.

5. A method of estimating channel response as claimed in claim 1 wherein the receiving device periodically updates the estimate of the channel response using the received data.

6. A method of estimating channel response as claimed in claim 5 wherein the transmit data is processed in block format and the channel response is updated for each block of received data.

7. A method of estimating channel response as claimed in claim 5 wherein the estimation of the channel response includes the additional step of using updated channel response coefficients to interpolate updated values for any channel response coefficients that have not been updated following comparison with the previous estimate of the channel response.

8. A method of estimating channel response as claimed in claim 1 wherein the estimate of the channel response is obtained by a recursive least square (RLS) algorithm.

9. A method of estimating channel response as claimed in claim 1 wherein the transmit data is processed in block format and the end of each data block is padded with zeros.

10. A communications method for use by a transmitting device having a plurality of transmit antennas in a communications system also comprising a receiving device having at least one receive antenna, the method comprising
a. superimposing training sequences onto transmit data to be transmitted by the transmit antennas
b. transmitting the data from step (a)
wherein the training sequences for each transmit antenna are arranged such that they are non-overlapping in the frequency domain.

11. A communications method as claimed in claim 10 wherein the transmit data is processed in block format and the end of each data block is padded with zeros.

12. A communications method as claimed in claim 10 wherein the training data at any one transmit antenna is unique to that antenna.

13. A communications method as claimed in claim 10 wherein the training sequences are based upon sequences of length K and the normalised discrete Fourier transform (DFT) of the length K training sequence at the qth transmit antenna is defined by the column vector x_{q} and
$${\prod }_{q = 1}^{n} {X}_{q} = 0$$
where X_{q} is a diagonal matrix with the elements of x_{q} on the diagonal, 0 is a K×K matrix of zeros, and the quantity n denotes the number of transmit antennas in the systems.

14. A communications method as claimed in claim 13 wherein training sequences are arranged such that
A=\sqrt{K}[X₁F_{L+1} . . . XₙF_{L+1}]
wherein A is a unitary matrix up to a scalar multiple, L≧the memory order of channel impulse response in the communications channel between the transmitting and receiving devices and F_{L+1} is a matrix comprising the first L+1 columns of the normalised DFT matrix.

15. A transmitting device having a plurality of transmit antennas for use in a communications system also comprising a receiving device having at least one receive antennas, the transmitting device comprising means for superimposing training sequences onto transmit data to be transmitted by the transmit antennas wherein the training sequences for each transmit antenna are arranged such that they are non-overlapping in the frequency domain.

16. A transmitting device as claimed in claim 15 wherein the transmit data is in block format and the end of each data block is padded with zeros.

17. A transmitting device as claimed in claim 15 wherein the training sequence at any one transmit antenna is unique to that antenna.

18. A transmitting device as claimed in claim 15 wherein the training sequences are based upon sequences of length K and the normalised discrete Fourier transform (DFT) of the length K training sequence at the qth transmit antenna is defined by the column vector x_{q} and
$${\prod }_{q = 1}^{n} {X}_{q} = 0$$
where X_{q} is a diagonal matrix with the elements of x_{q} on the diagonal, 0 is a K×K matrix of zeros, and the quantity n denotes the number of transmit antennas in the systems.

19. A transmitting device as claimed in claim 18 wherein training sequences are arranged such that
A=\sqrt{K}[X₁F_{L+1} . . . XₙF_{L+1}]
wherein A is a unitary matrix up to a scalar multiple, L≧the memory order of channel impulse response in the communications channel between the transmitting and receiving devices and F_{L+1} is a matrix comprising the first L+1 columns of the normalised DFT matrix.

20. A communications method for use by a receiving device having at least one receive antenna in a communications system also comprising a transmitting device having a plurality of transmit antennas, the method comprising
a) receiving data that has been transmitted from the transmitter, the transmit message comprising training sequences superimposed onto transmit data, and then performing the following steps across all channels
b) Equalising received data to remove channel distortion,
c) detecting an estimate for the transmit data,
d) using the estimate of the transmit data from step (c) in order to derive an estimate of the received training sequences as modified by the channel response from the received data,
e) comparing the estimate of channel modified training sequences from step (d) with original training sequences in order to estimate the channel response

21. A communications method as claimed in claim 20 wherein the receiving device comprises a previous estimate of the channel response and step (c) comprises subtracting the estimate of the transmit data as modified by the previous estimate of the channel response from the received data and step (e) comprises updating the previous estimate of the channel response.

22. A communications method as claimed in claim 20 wherein the training sequence at any one transmit antenna is unique to that antenna.

23. A communications method as claimed in any of claims 20 to 22 wherein the training sequences for each transmit antenna are arranged such that they are non-overlapping in the frequency domain.

24. A communications method as claimed in claim 20 wherein received data is equalised by one of the following methods: linear zero forcing (ZF), minimum mean square error (MMSE) equalisation non-linear maximum likelihood (ML) or decision feedback.

25. A communications method as claimed in claim 20 wherein the receiving device periodically updates the estimate of the channel response using the received data.

26. A communications method as claimed in claim 20 wherein the transmit data is processed in block format and the channel response is updated for each block of received data.

27. A communications method as claimed in claim 21 wherein the estimation of the channel response includes the additional step of using updated channel response coefficients to interpolate updated values for any channel response coefficients that have not been updated following comparison with the previous estimate of the channel response.

28. A communications method as claimed in claim 20 wherein the estimate of the channel response is obtained by a recursive least square (RLS) algorithm.

29. A receiving device having at least one receive antenna for use in a communications system also comprising a transmitting device having a plurality of transmit antennas and transmitting training sequences superimposed onto transmit data, the receiving device comprising
a) means for equalising received data to remove channel distortion,
b) means for detecting an estimate for the transmit data,
c) means for deriving an estimate of the received training data as modified by the channel response from the received data using the estimate of the transmit data,
d) means for comparing the estimate of channel modified training sequences from step (c) with original training sequences in order to estimate the channel response

30. A receiving device as claimed in claim 29 wherein the receiving device comprises a previous estimate of the channel response and the means of step (c) subtracts the estimate of the transmit data as modified by the previous estimate of the channel response from the received data and the means of step (d) updates the previous estimate of the channel response.

31. A receiving device as claimed in claim 29 wherein the training data at any one transmit antenna is unique to that antenna.

32. A receiving device as claimed in claim 29 wherein the training sequences for each transmit antenna are arranged such that they are non-overlapping in the frequency domain.

33. A receiving device as claimed in claim 29 wherein the means for equalising received data is by one of the following: linear zero forcing (ZF), minimum mean square error (MMSE) equalisation, non-linear maximum likelihood (ML) or decision feedback.

34. A receiving device as claimed in claim 29 wherein the receiving device periodically updates the estimate of the channel response using the received data.

35. A receiving device as claimed in any of claims 31 to 34 wherein the transmit data is processed in block format and the channel response is updated for each block of received data.

36. A receiving device as claimed in claim 30 wherein the means for estimating the channel response additionally interpolates updated values for any channel response coefficients that have not been updated following comparison with the previous estimate of the channel response.

37. A receiving device as claimed in claim 29 wherein the means for estimating the channel response incorporates a recursive least square (RLS) algorithm.

38. An operating program which, when run on a communications device, causes the device to carry out a method as claimed in claim 10.

39. An operating program as claimed in claim 38, carried on a carrier medium.

40. An operating program as claimed in claim 39, wherein the carrier medium is a transmission medium.

41. An operating program as claimed in claim 39, wherein the carrier medium is a storage medium.

42. A communications system comprising:
a transmitting device having a plurality of transmit antennas and means for superimposing training data onto transmit data to be transmitted by the transmit antennas, the training data being arranged such that training sequences are non-overlapping in the frequency domain;
a receiving device having a plurality of receive antennas and
i. means for equalising received data to remove channel distortion,
ii. means for detecting an estimate for the transmit data,
iii. means for deriving an estimate of the received training data as modified by the channel response from the received data using the estimate of the transmit data, and
iv. means for comparing estimate of received training data from step iii with original training data in order to estimate the channel response
